(19) United States
(12) Patent Application Publication
(10) Pub. No.: US 2026/0082825 A1
(43) Pub. Date: Mar. 19, 2026

(54) SELECTION ELEMENT IN WHICH METAL ELEMENT IS DIFFUSED IN CHALCOGENIDE

(71) Applicant: IUCF-HYU (INDUSTRY-UNIVERSITY COOPERATION FOUNDATION HANYANG UNIVERSITY), Seoul (KR)

(72) Inventor: Jin Pyo HONG, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 19/400,305

(22) Filed: Nov. 25, 2025

Related U.S. Application Data
(63) Continuation of application No. PCT/KR2024/005103, filed on Apr. 17, 2024.

(30) Foreign Application Priority Data
Jun. 19, 2023 (KR) 10-2023-0077879

(51) Int. Cl. H10N 70/20; H10N 70/00

(52) U.S. Cl. CPC H10N 70/245; H10N 70/8416; H10N 70/8822; H10N 70/8825; H10N 70/8828

(57) ABSTRACT

A selector device exhibiting excellent nonlinearity and bidirectional switching characteristics includes a resistance-changing layer formed of a chalcogenide material. Metal ions supplied from a metal supply layer pass through a diffusion control layer. For this purpose, a voltage equal to or higher than a threshold voltage is applied, and metal ions having energy equal to or higher than a predetermined level are distributed within the resistance-changing layer. When a voltage is applied for switching operation, a low-resistance state or a high-resistance state is implemented by electron hopping.

### CROSS-REFERENCE TO RELATED APPLICATIONS

This application is a bypass continuation of pending PCT International Application No. PCT/KR2024/005103, which was filed on April 17, 2024, and which claims priority from Korean Patent Application No. 10-2023-0077879 filed on June 19, 2023. The entire contents of the aforementioned patent applications are incorporated herein by reference.

### TECHNICAL FIELD

The present disclosure relates to a selector device, and more particularly, to a selector device with a ruthenium (Ru) metal element diffused in a chalcogenide composed of group 14 to 16 elements.

### BACKGROUND ART

In a cross-point memory, word lines and bit lines intersect perpendicularly to each other, and memory cells are disposed at the intersections. Each memory cell exhibits a resistance-changing characteristic in which its resistance varies depending on the applied conditions. Each memory cell includes a single selector device and a single resistance-changing layer. The selector device and the resistance-changing layer may be stacked perpendicularly to each other.

The cross-point memory has a very simple configuration, and its cells can be cumulatively stacked, which is advantageous for forming a three-dimensional structure. Accordingly, it has attracted attention as a next-generation memory capable of replacing flash memory in the field of non-volatile memory. The resistance-changing layer constituting the cross-point memory may be a single layer or may have a structure in which multiple functional layers are stacked perpendicularly to each other. For example, in phase change RAM (PRAM), a phase change layer is used as a resistance-changing layer, and in magnetic RAM (MRAM), a change in resistance is induced through a stacked structure including a pinned layer having fixed magnetization, a tunneling insulating layer, and a free layer having variable magnetization. In resistive change RAM (ReRAM), a resistance-changing layer in which conductive filaments are formed and ruptured is employed.

An additional switching operation is required for the above-described resistance-changing layer to be electrically connected to a predetermined word line or bit line. A select transistor is used to perform this switching operation. The select transistor may be disposed between the bit line and the resistance-changing layer, or between the word line and the resistance-changing layer, wherein the resistance-changing layer of a selected cell is accessed through the switching operation. However, the involvement of the select transistor has a disadvantage in that it increases the area of each unit cell.

To address this issue, a selector device capable of performing a selection operation without using a transistor is employed. The selector device exhibits high conductivity within a specific range of applied voltages and may be integrally formed above or below the resistance-changing layer. The selector device may be made of, for example, a multi-element chalcogenide material, a metal oxide material, a Cu ion migration-based material, or a tunneling behavior-based material.

The multi-element chalcogenide-based material employs an Ovonic Threshold Switching (OTS) mechanism using a material such as AsTeGeSiN. This material exhibits a relatively high threshold voltage and poses difficulty in precisely controlling its composition ratio.

Furthermore, the metal oxide-based material exhibits the highest on/off ratio among selector devices; however, due to the inherent characteristics of oxides, it is difficult to ensure reliability. In addition, the Cu ion migration-based material has a narrow margin in composition ratio, and the tunneling behavior-based material employing NbO₂ or HfO₂ exhibits a low on/off ratio and poses difficulty in ensuring reliability.

Accordingly, there remains a demand for the development of a selector device or switch that exhibits improved nonlinearity and bidirectional switching characteristics.

### DETAILED DESCRIPTION OF THE INVENTION

### Technical Problem

The technical objective of the present disclosure is to provide a selector device that exhibits bidirectional switching characteristics.

### Technical Solution

To solve the above-described technical problem, the present disclosure provides a selector device comprising: a lower electrode; a resistance-changing layer formed on the lower electrode and configured to implement a low-resistance state or a high-resistance state based on electron hopping between metal ions; a diffusion control layer formed on the resistance-changing layer and configured to control migration of the metal ions into the resistance-changing layer; a metal supply layer formed on the diffusion control layer and configured to supply the metal ions to the resistance-changing layer through the diffusion control layer; and an upper electrode formed on the metal supply layer.

The technical problem of the present disclosure is also solved by providing a selector device comprising: a lower metal supply layer formed on a lower electrode; a lower diffusion control layer formed on the lower metal supply layer and configured to control migration of metal ions supplied from the lower metal supply layer; a resistance-changing layer formed on the lower diffusion control layer and configured such that electron hopping occurs based on the distribution of the supplied metal ions; an upper diffusion control layer formed on the resistance-changing layer and configured to control migration of the metal ions; an upper metal supply layer formed on the upper diffusion control layer and configured to supply the metal ions to the resistance-changing layer through the upper diffusion control layer; and an upper electrode formed on the upper metal supply layer.

### Effects of the Invention

According to the present disclosure described above, metal ions are introduced into a resistance-changing layer formed of a chalcogenide material. However, a diffusion control layer may be provided adjacent to the resistance-changing layer to partially block diffusion of the metal ions. Due to the diffusion control layer, the metal ions can be introduced into the resistance-changing layer only when a voltage equal to or higher than a predetermined threshold voltage is applied. Therefore, the metal ions are uniformly distributed within the resistance-changing layer. The resistance-changing layer is in an amorphous state of a chalcogenide and is provided in a form in which lone pairs of electrons are minimized. When a high voltage or a voltage equal to or higher than a threshold voltage is applied in a state where the metal ions are uniformly distributed, the metal ions become activated and serve as hopping sites for electrons, thereby implementing a low-resistance state. In contrast, when a voltage lower than the threshold voltage is applied, the metal ions are stabilized, thereby implementing a high-resistance state.

The above-described structure and operation serve to ensure symmetrical bidirectional switching characteristics, thereby allowing the device to function as a switching element.

### BRIEF DESCRIPTION OF THE DRAWINGS

FIG. 1 is a cross-sectional view illustrating a selector device according to a preferred embodiment of the present disclosure.

FIG. 2 is a schematic diagram illustrating the operation of the selector device of FIG. 1 according to a preferred embodiment of the present disclosure.

FIG. 3 is a graph illustrating the on/off characteristics of a selector device according to Measurement Example 1 of the present disclosure.

FIG. 4 is another cross-sectional view illustrating a selector device according to a preferred embodiment of the present disclosure.

FIG. 5 is a schematic diagram illustrating the operation of the selector device of FIG. 4 according to a preferred embodiment of the present disclosure.

### BEST MODE FOR CARRYING OUT THE INVENTION

As the present disclosure allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. Throughout the description of each drawing, like reference numerals are used for like components.

Unless defined otherwise, all terms used herein including technical or scientific terms have the same meaning as those generally understood by those skilled in the art to which the present invention pertains. It will be further understood that terms defined in dictionaries that are commonly used should be interpreted as having meanings that are consistent with their meanings in the context of the relevant art and should not be interpreted as having ideal or excessively formal meanings unless clearly defined in the present disclosure.

Hereinafter, preferred embodiments of the present disclosure will be described in more detail with reference to the accompanying drawings.

### EMBODIMENT

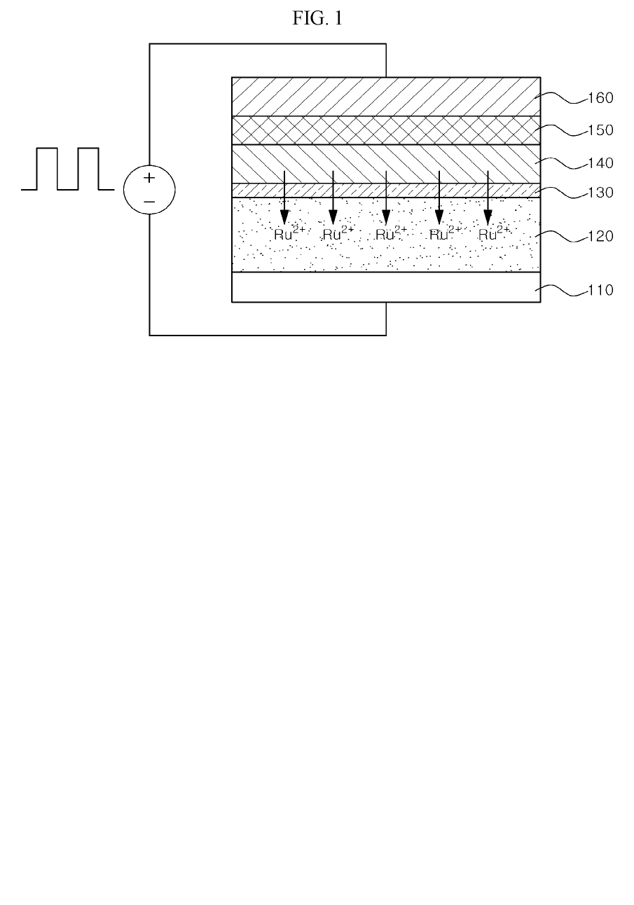

FIG. 1 is a cross-sectional view illustrating a selector device according to a preferred embodiment of the present disclosure.

Referring to FIG. 1, the selector device comprises a lower electrode 110, a resistance-changing layer 120, a diffusion control layer 130, a metal supply layer 140, a diffusion barrier layer 150, and an upper electrode 160.

The lower electrode 110 formed on a substrate 100 is preferably made of W or TiN; however, any other conductive material may also be used as long as the material does not undergo a change in its physical properties during the process of forming films, such as the resistance-changing layer 120, thereon.

A resistance-changing layer 120 is provided on the lower electrode 110. The resistance-changing layer 120 is composed of GeS₂ and is required to have an amorphous phase. The amorphous phase exhibits an irregular structure, thereby forming spaces within the film through which Ru metal can readily diffuse. The GeS₂, which is a chalcogenide material, has the characteristic that diffusion of Ru metal readily occurs.

The resistance-changing layer 120 is required to have a thickness of 2 nm to 20 nm. If the thickness of the resistance-changing layer 120 is less than 2 nm, the uniformity of Ru metal ions within the amorphous GeS₂ matrix cannot be ensured. In contrast, if the thickness of the resistance-changing layer 120 exceeds 20 nm, the diffusion path for Ru metal ions becomes too long, making it difficult to achieve smooth switching operation.

A diffusion control layer 130 is provided on the resistance-changing layer 120, and the diffusion control layer 130 is made of Ti. In particular, the diffusion control layer 130 preferably has a thickness of 1 nm to 2 nm. If the thickness of the diffusion control layer 130 is less than 1 nm, it becomes difficult to ensure the uniformity of the film, and regions in which a large amount of Ru metal ions are locally distributed may appear. In contrast, if the thickness of the diffusion control layer 130 exceeds 2 nm, Ru atoms from the metal supply layer 140 cannot pass through the diffusion control layer 130 even when an electrical stimulus is applied.

A metal supply layer 140 is provided on the diffusion control layer 130. The metal supply layer 140 contains Ru. The metal supply layer 140 can supply Ru metal atoms or Ru metal ions into the resistance-changing layer 120 when an electrical stimulus is applied. During the process in which Ru metal ions are supplied into the resistance-changing layer 120, the diffusion control layer 130 functions as a valve that controls the transfer of Ru metal ions.

In addition, a diffusion barrier layer 150 may be further provided on the metal supply layer 140. The diffusion barrier layer 150 may be made of Ti or a Ti alloy and preferably has a thickness greater than that of the diffusion control layer 130. That is, when an electrical stimulus is applied to the metal supply layer 140, the diffusion barrier layer 150 prevents Ru atoms from the metal supply layer 140 from diffusing toward the upper electrode 160. For this purpose, the diffusion barrier layer 150 preferably has a thickness of 2 nm to 10 nm.

An upper electrode 160 is formed on the above diffusion barrier layer 150. The upper electrode 160 may be made of any conductive metal material, and for example, Pt may be used.

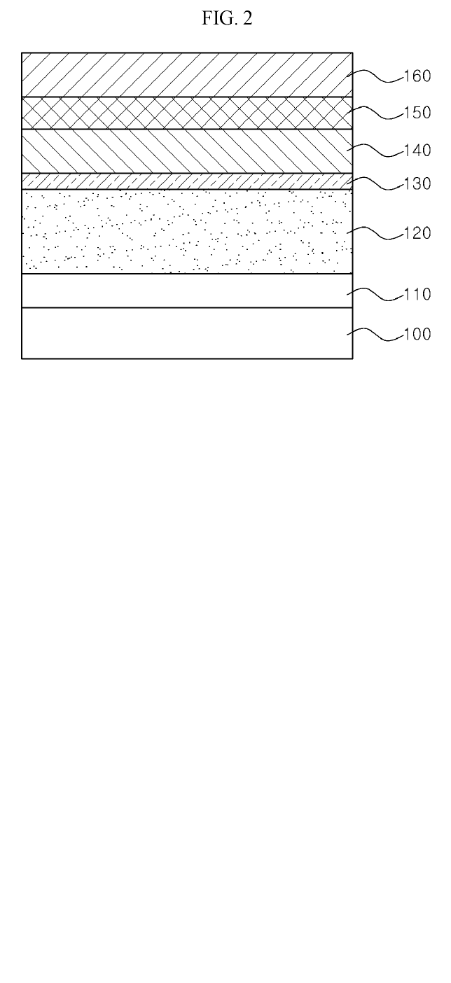

FIG. 2 is a schematic diagram illustrating the operation of the selector device of FIG. 1 according to a preferred embodiment of the present disclosure.

Referring to FIG. 2, an electrical stimulus is applied between the upper electrode 160 and the lower electrode 110. The electrical stimulus is in the form of a pulse train. Upon application of the electrical stimulus in the form of a pulse train, Ru metal ions from the metal supply layer 140 pass through the diffusion control layer 130 and flow into the resistance-changing layer 120.

The resistance-changing layer 120 has an amorphous GeS₂. In the amorphous GeS₂ the number of lone pairs of electrons is minimized. Therefore, the formation of coordination bonds between the lone pairs of electrons in the GeS₂ and the Ru metal ions is minimized, thereby reducing interference with the formation of an activated state of the Ru metal ions.

Moreover, due to the arrangement of the diffusion control layer 130, only Ru metal ions having a specific energy or higher can pass through the diffusion control layer 130. Therefore, the phenomenon in which low-energy Ru metal ions become concentrated only in the upper region of the resistance-changing layer 120 is prevented, and the Ru metal ions can be uniformly distributed within the resistance-changing layer 120. That is, for the Ru metal ions from the metal supply layer 140 to pass through the diffusion control layer 130 and be distributed in the resistance-changing layer 120, an electrical stimulus with a level equal to or higher than a threshold voltage needs to be applied.

Furthermore, the Ru metal ions are uniformly distributed within the amorphous GeS₂, and the individual Ru metal ions become activated to induce electron hopping, thereby implementing a low-resistance state. To this end, a positive or negative voltage is applied between the upper electrode and the lower electrode, and the applied voltage causes the Ru metal ions to be excited (activated). Electrons within the resistance-changing layer 120 hop between the excited Ru metal ions, thereby implementing a low-resistance state. That is, the excited Ru metal ions form a conductive channel and serve as hopping sites for electrons.

When a low-level voltage is applied to the upper electrode 160 and the lower electrode 110 after the low-resistance state, the Ru metal ions become stable, and electron hopping does not occur. As a result, a high-resistance state is implemented.

### Preparation Example 1

A lower electrode is formed on a SiO₂ substrate, and W is used as the material for the lower electrode. A GeS₂ layer having a thickness of 15 nm is formed as a resistance-changing layer on the lower electrode by sputtering. The resulting GeS₂ layer has a thickness of 15 nm. Subsequently, sputtering is performed using a prepared Ti target to form a diffusion control layer made of Ti having a thickness of 1 nm. A metal supply layer made of Ru is formed on the diffusion control layer made of Ti with a thickness of 3 nm. Subsequently, a diffusion barrier layer made of Ti is formed on the metal supply layer with a thickness of 2 nm, and an upper electrode made of Pt is formed on the diffusion barrier layer with a thickness of 100 nm.

### Measurement Example 1

The lower electrode of the selector device prepared in Preparation Example 1 is grounded, and then an electrical stimulus is applied through the upper electrode using a DC signal. The DC signal is first applied from 0 V to 6 V in 0.02 V increments, and then, conversely, from 0 V to -6 V in 0.02 V increments. By the application of the DC electrical stimulus, Ru metal ions pass through the diffusion control layer and become uniformly distributed within the GeS₂ layer. In a state where the Ru metal ions are uniformly distributed within the GeS₂ layer, a bias is applied between the upper electrode and the lower electrode to measure the on/off characteristics.

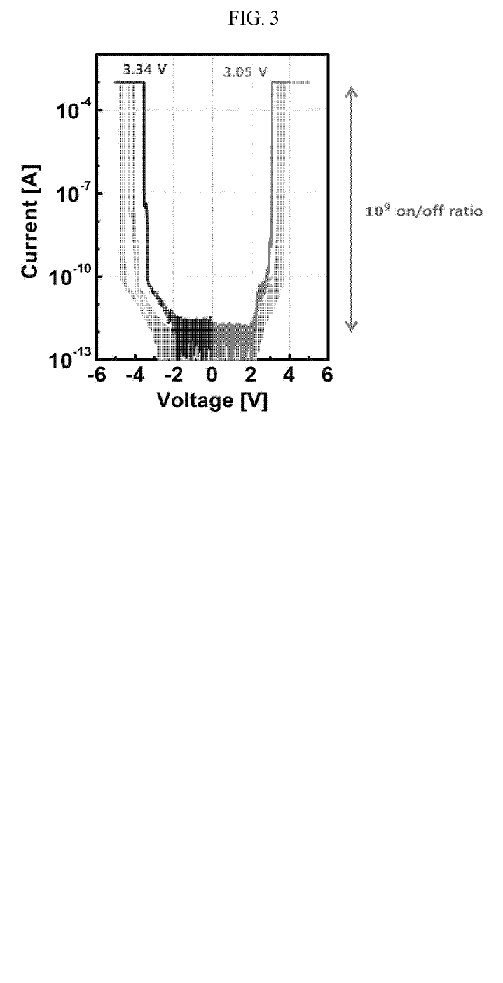

FIG. 3 is a graph illustrating the on/off characteristics of the selector device according to Measurement Example 1 of the present disclosure.

Referring to FIG. 3, while a DC voltage is applied to the upper electrode with respect to the lower electrode, the current flowing through the selector device is measured. For accurate measurement, the voltage was swept until the selector device reached a complete low-resistance or turn-on state. The voltage applied through the upper electrode ranged from -6 V to +6 V. The voltage sweep was performed ten times.

When the voltage applied to the upper electrode is swept from -6 V to +6 V during the first four cycles, variations in the turn-on voltage are observed in the negative voltage range. Moreover, the selector device abruptly transitions to a low-resistance state at voltage levels between -5 V and -4 V. This phenomenon cannot be explained by conventional mechanisms involving the formation and rupture of conductive channels or filaments due to the migration of metal ions or oxygen vacancies. Since the resistance-changing layer is composed of GeS₂ or a chalcogenide material, oxygen ions are not generated within the resistance-changing layer. Furthermore, it is impossible for Ru metal ions, which are heavy metals, to actively migrate within the amorphous resistance-changing layer at a voltage level below the threshold voltage. Therefore, the implementation of a low-resistance state upon application of a negative voltage to the upper electrode cannot be attributed to the migration of metal ions or oxygen vacancies.

This phenomenon can be explained by the electron hopping that occurs between excited Ru metal ions within the resistance-changing layer, in a state where the Ru metal ions distributed within the resistance-changing layer either do not migrate or migrate only weakly. For example, when a high negative voltage is applied, the Ru metal ions introduced into the resistance-changing layer enter an excited state, and the excited Ru metal ions serve as hopping sites for electrons, thereby implementing a low-resistance state.

During the first four repeated measurements, the hopping sites appear somewhat unstable, and variations in the turn-on voltage are observed when a negative voltage is applied. However, after five or more cycles, the turn-on voltage becomes stabilized at a constant level. When a positive voltage is applied, the turn-on voltage also fluctuates slightly during the first four cycles but remains more stable than in the case of the negative voltage application. After five or more cycles, the turn-on voltage becomes constant. Therefore, the following description of the operation is based on voltage sweeps applied five times or more.

When the voltage difference between the upper electrode and the lower electrode is about 3 V or higher, a low-resistance state is implemented, and the selector device is turned on. When the voltage difference is 2 V or lower, a current of 10⁻¹² A flows, thereby implementing a high-resistance state. This high-resistance state is maintained until the voltage difference between the two electrodes reaches -3 V.

Additionally, when the voltage difference between the upper electrode and the lower electrode reaches -3.34 V, the selector device again enters the low-resistance state. This confirms that the selector device exhibits bidirectional switching characteristics.

In the on/off operation of the selector device, the on/off current ratio is confirmed to be 10⁹.

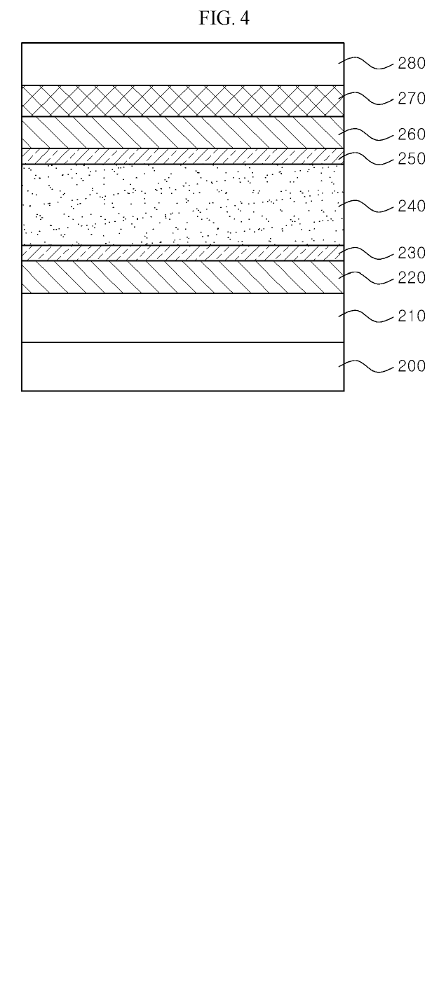

FIG. 4 is another cross-sectional view illustrating a selector device according to a preferred embodiment of the present disclosure.

Referring to FIG. 4, a lower electrode 210, a lower metal supply layer 220, a lower diffusion control layer 230, a resistance-changing layer 240, an upper diffusion control layer 250, an upper metal supply layer 260, a diffusion barrier layer 270, and an upper electrode 280 are provided on a substrate 200.

The resistance-changing layer 240, the upper diffusion control layer 250, the upper metal supply layer 260, the diffusion barrier layer 270, and the upper electrode 280 have the same configurations as those shown in FIG. 1, except that the thickness of the resistance-changing layer 240 is increased to a range of 2 nm to 8 nm.

In FIG. 4, a lower metal supply layer 220 and a lower diffusion control layer 230 are further provided between the lower electrode 210 and the resistance-changing layer 240. The lower metal supply layer 220 includes Ru, and the lower diffusion control layer 230 includes Ti. That is, the lower metal supply layer 220 is preferably formed of the same material and has the same thickness as the upper metal supply layer 260. Likewise, the lower diffusion control layer 230 is preferably formed of the same material and has the same thickness as the upper diffusion control layer 250.

As the metal supply layer 220 and the diffusion control layer 230 are disposed below the resistance-changing layer 240, bidirectional switching characteristics can be ensured even when the thickness of the resistance-changing layer 240 increases. In addition, Ru metal ions are supplied from both the upper and lower sides of the resistance-changing layer 240, thereby achieving a uniform distribution of Ru metal ions within the resistance-changing layer 240.

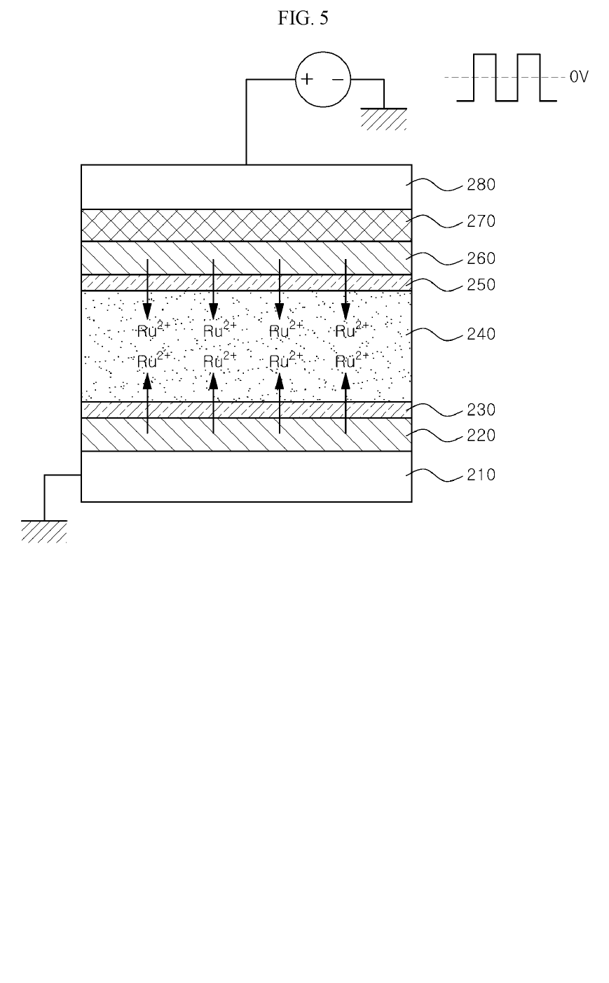

FIG. 5 is a schematic diagram illustrating the operation of the selector device of FIG. 4 according to a preferred embodiment of the present disclosure.

Referring to FIG. 5, an electrical stimulus is applied between the lower electrode 210 and the upper electrode 280. The electrical stimulus is in the form of a pulse train in which positive and negative voltages are alternately applied between the upper electrode 280 and the lower electrode 210. For the application of the electrical stimulus, the lower electrode 210 is grounded, and the positive and negative voltages are alternately applied through the upper electrode 280.

When a positive voltage is applied, Ru metal ions diffuse from the upper metal supply layer 260 through the upper diffusion control layer 250 into an upper region of the resistance-changing layer 240. In contrast, when a negative voltage is applied, Ru metal ions are supplied from the lower metal supply layer 220 through the lower diffusion control layer 230 into a lower region of the resistance-changing layer 240. Accordingly, even when the thickness of the resistance-changing layer 240 increases, a uniform distribution of Ru metal ions can be achieved throughout the entire volume of the resistance-changing layer 240.

Moreover, the structure of the selector device shown in FIG. 4 can provide more symmetrical bidirectional characteristics compared to that shown in FIG. 1. Since the selector device of FIG. 4 has a symmetrical structure centered on the resistance-changing layer 240, more symmetrical characteristics are ensured during the switching operation. Furthermore, although the data obtained from the Preparation Example and Measurement Example of the present disclosure was when the resistance-changing layer was specifically composed of GeS₂, it is expected that the resistance-changing layer will exhibit the same or similar operation when a chalcogenide material is used. For example, the resistance-changing layer may comprise GeTe₂, GeSe₂, SiS₂, SiTe₂, SiSe₂, or a Si-Ge-S-Te-Se alloy, in addition to GeS₂. The diffusion control layer may comprise TiN, Ta, or TaN, in addition to Ti.

According to the present disclosure, metal ions are introduced into a resistance-changing layer formed of a chalcogenide material. However, a diffusion control layer may be provided adjacent to the resistance-changing layer to partially block diffusion of the metal ions. Due to the diffusion control layer, the metal ions can be introduced into the resistance-changing layer only when a voltage equal to or higher than a predetermined threshold voltage is applied. Therefore, the metal ions are uniformly distributed within the resistance-changing layer. The resistance-changing layer is in an amorphous state of a chalcogenide and is provided in a form in which lone pairs of electrons are minimized. When a high voltage or a voltage equal to or higher than a threshold voltage is applied in a state where the metal ions are uniformly distributed, the metal ions become activated and serve as hopping sites for electrons, thereby implementing a low-resistance state. Furthermore, when a voltage lower than the threshold voltage is applied, the metal ions are stabilized, thereby implementing a high-resistance state.

The above-described structure and operation serve to ensure symmetrical bidirectional switching characteristics, thereby allowing the device to function as a switching element.

What is claimed is:

1. A selector device comprising:
a lower electrode;
a resistance-changing layer formed on the lower electrode and configured to implement a low-resistance state or a high-resistance state based on electron hopping between metal ions;
a diffusion control layer formed on the resistance-changing layer and configured to control migration of the metal ions into the resistance-changing layer;
a metal supply layer formed on the diffusion control layer and configured to supply the metal ions to the resistance-changing layer through the diffusion control layer; and
an upper electrode formed on the metal supply layer.

2. The selector device according to claim 1, wherein the resistance-changing layer comprises an amorphous chalcogenide material.

3. The selector device according to claim 2, wherein the resistance-changing layer comprises GeS₂.

4. The selector device according to claim 2, wherein the resistance-changing layer comprises GeTe₂, GeSe₂, SiS₂, SiTe₂, SiSe₂, or a Si-Ge-S-Te-Se alloy.

5. The selector device according to claim 1, wherein the diffusion control layer comprises Ti.

6. The selector device according to claim 1, wherein the metal supply layer comprises Ru.

7. The selector device according to claim 6, wherein Ru metal ions from the metal supply layer are distributed within the resistance-changing layer by passing through the diffusion control layer when a voltage equal to or higher than a threshold voltage is applied.

8. The selector device according to claim 7, wherein the Ru metal ions are excited at the voltage equal to or higher than the threshold voltage and serve as hopping sites for electrons.

9. A selector device comprising:
a lower metal supply layer formed on a lower electrode;
a lower diffusion control layer formed on the lower metal supply layer and configured to control migration of metal ions supplied from the lower metal supply layer;
a resistance-changing layer formed on the lower diffusion control layer and configured such that electron hopping occurs based on a distribution of the supplied metal ions;
an upper diffusion control layer formed on the resistance-changing layer and configured to control the migration of the metal ions;
an upper metal supply layer formed on the upper diffusion control layer and configured to supply the metal ions to the resistance-changing layer through the upper diffusion control layer; and
an upper electrode formed on the upper metal supply layer.

10. The selector device according to claim 9, wherein when a positive voltage is applied through the upper electrode, the metal ions from the upper metal supply layer are supplied to the resistance-changing layer through the upper diffusion control layer, and when a negative voltage is applied through the upper electrode, metal ions from the lower metal supply layer are supplied to the resistance-changing layer through the lower diffusion control layer.

11. The selector device according to claim 9, wherein the resistance-changing layer comprises GeS₂ GeTe2, GeSe2, SiS2, SiTe2, SiSe2, or a Si-Ge-S-Te-Se alloy.

12. The selector device according to claim 9, wherein the upper diffusion control layer and the lower diffusion control layer have the same thickness and comprise Ti.

13. The selector device according to claim 9, wherein the upper metal supply layer and the lower metal supply layer comprise Ru.
